(19) United States
(12) Patent Application Publication
(10) Pub. No.: US 2025/0305110 A1
(43) Pub. Date: Oct. 2, 2025

(54) METAL FREE COATING COMPRISING TETRAHEDRAL HYDROGEN-FREE AMORPHOUS CARBON

(71) Applicant: Oerlikon Surface Solutions AG, Pfäffikon, Pfäffikon (CH)

(72) Inventors: Vishal KHETAN, Sargans (IN); Andreas REITER, Schaanwald (AT)

(21) Appl. No.: 18/881,221

(22) PCT Filed: Jul. 6, 2023
(86) PCT No.: PCT/EP2023/068803

§ 371 Date: Jan. 3, 2025

(30) Foreign Application Priority Data
Jul. 6, 2022 (DE) 10 2022 116 906.5

(51) Int. Cl. C23C 14/06; C23C 14/32

(52) U.S. Cl. CPC C23C 14/0605; C23C 14/325

(57) ABSTRACT

The invention relates to a coated substrate, preferably coated tool for use in manufacturing processes, such as machining processes or forming processes, comprising a coated surface, said coated surface formed by a substrate surface made of a first material (1) and a coating system, preferably an arc-PVD-deposited coating system, applied on said substrate surface, said coating system comprising an amorphous carbon film (100), wherein the amorphous carbon film (100) is a tetrahedral hydrogen-free amorphous carbon film in which the share of the sp³ bond percentages of the C—C bonds exceeds that of the sp² bond percentages. The invention further relates to a method.

The present invention relates to a coated substrate, in particular a coated tool, with a metal free coating comprising a tetrahedral hydrogen-free amorphous carbon film with enhanced toughness and a method for producing thereof.

### PRIOR ART

Ohtani et al propose in EP 1266979 B1 to produce an amorphous carbon coated tool by specifying the component of the base material and the thickness of the amorphous carbon film. The method suggested in EP 1266979 B1 for fabricating an amorphous carbon coated tool includes the steps of supporting in a vacuum vessel a base material of WC base cemented carbide, and applying zero or negative direct current bias to the base material and vaporizing the graphite that is the source material to form an amorphous carbon film. The maximum thickness of the amorphous carbon film at the cutting edge is controlled to be 0.05 μm to 0.8 μm. The use of graphite as the material source for forming the amorphous carbon film by physical vapor deposition under an atmosphere absent of hydrogen is suggested, so that the amorphous carbon film comprises not more than 5% by atom of hydrogen. Further, in particular the use of a cathode arc ion plating method and a temperature between 50° C. and 350° C. is suggested.

Furthermore, Ohtani et al. suggest to use appropriate measures to prevent scattering of particles from the graphite material for improving the surface roughness of the amorphous carbon film, for example by growing a film through low energy or by using a filter by a magnetic field. The suggested roughness is between 0.002 μm and 0.05 μm in Ra. The suggested Knoop hardness is between 20 GPa and 50 GPa. The amorphous carbon film in is transparent in the visible region, and exhibits interference color, where the color of the coated film may be the rainbow color corresponding to a plurality of color tones instead of a single color. The coated tool has an interlayer provided between the base material and the amorphous carbon film to enhance the adherence of the amorphous carbon film, where for the interlayer, at least one type of element selected from the group consisting of an element from Groups IVa, Va, VIa and IIIb of the periodic table and from Group IVb of the periodic table excluding C, or carbide of at least one type of element selected from the group consisting of these elements can be used, in particular it is suggested that the interlayer includes at least one type of element selected from the group consisting of elements Ti, Zr, Hf, V, Nb, Ta, Cr, Mo, W and Si, or carbide of at least one type of element selected from the group consisting of these elements, and that the thickness of the interlayer is between 0.5 nm and 10 nm.

Becker et al. propose in WO 2021/019084 A1 a method for producing a hydrogen-free amorphous carbon coating having a lower hardness closer to the substrate and at the outer surface of the coating, and a higher hardness anywhere between these two regions. For obtaining these desired coating transitions Becker et al. propose to control bias voltage and substrate temperature and using cathodic arc evaporation techniques, applying low target currents in a range of 25 A to 35 A for the deposition of the hydrogen-free amorphous carbon coating. Furthermore, Becker et al. propose to deposit a metal layer as adhesion layer for improving the adhesion between the substrate and the hydrogen-free amorphous carbon coating. A such coating solution is very suitable for components used in automotive applications but not for tools used in cutting or forming applications.

### Objective of the Present Invention

The main objective of the present invention is to provide a coated substrate, in particular a coated tool, exhibiting tribological properties comparable to the properties of hydrogen free tetrahedral amorphous carbon coatings but preferably exhibiting a higher toughness in comparison with the prior art, especially for attaining an enhanced performance and increased life-time, in particular for tools used in cutting or forming applications independently of the hardness of the substrate (i.e. in case of a coated tool, then for attaining an increased tool performance and increased life-time).

### Description of the Present Invention

The present invention provides a coating solution, in particular as a first aspect a coated substrate and as a second aspect a method for producing the inventive coated substrate.

The main embodiment of a coated substrate according to the present invention is a coated substrate as described in claim 1, being preferably a coated tool for use in manufacturing processes, such as machining processes or forming processes, comprising a coated surface, said coated surface formed by a substrate surface made of a first material and a coating system, preferably an arc-PVD-deposited coating system (PVD=Physical Vapor Deposition), applied on said substrate surface, said coating system comprising an amorphous carbon film, wherein the amorphous carbon film is a tetrahedral hydrogen-free amorphous carbon film in which the share of the sp3 bond percentages of the C—C bonds exceeds that of the sp2 bond percentages, is provided.

According to the present invention the amorphous carbon film 100 is preferably designed comprising a variable ratio of the share of the sp³ bond percentages of the C—C bonds in relation to that of the sp² bond percentages along its thickness, wherein said ratio increasing, e.g. increasing continuously and/or stepwise, from the bottom to the top of the amorphous carbon film 100, wherein the bottom is the region of the amorphous carbon film 100 nearest to the substrate and the top is the region of the amorphous carbon film 100 most distant from the substrate.

According to a preferred embodiment the amorphous carbon film 100 is formed as multilayered film comprising at least two tetrahedral hydrogen-free amorphous carbon layers, wherein the at least two layers are:
a bottom layer 120 comprising the region of the amorphous carbon film 100 nearest to the substrate, and
a top layer 150 comprising the region of the amorphous carbon film 100 most distant from the substrate, wherein said ratio of the share of the sp³ bond percentages of the C—C bonds in relation to that of the sp² bond percentages is higher along the thickness of the top layer 150 than that along the thickness of the bottom layer 120.

In a most preferred embodiment the top layer 150 is the outermost layer of the amorphous carbon film 100. This allows especially attaining a very high tool performance of tools coated in this manner, in particular when the coated tool is used in cutting and forming applications.

For improving adhesion of the amorphous carbon film 100 to the substrate, the amorphous carbon film 100 is preferably deposited on said substrate surface in such a manner that an interface layer 10 is formed between the first material 1 of said substrate surface and the amorphous carbon film 100, wherein the interface layer consists of carbon implanted material, the carbon implanted material being formed of first material plus carbon implanted into it, wherein the thickness of the interface layer 10 is at least 3 nm.

For further improving adhesion of the amorphous carbon film 100 to the substrate, a transition layer 30 is deposited between the interface layer 10 and the amorphous carbon film 100, wherein the transition layer 30 is a carbon layer improving interfacial transition between the interface layer 10 and the amorphous carbon film 100.

Preferably the transition layer 30 is a tetrahedral hydrogen-free amorphous carbon layer.

According to a very preferred embodiment of the present invention the amorphous carbon film 100 has a low residual compressive stress, corresponding to a value in absolute value not higher than 5.5 GPa, preferably in a range from 2.8 GPa to 5.5 GPa, still more preferably in a range from 3 GPa to 5 GPa (values measured in particular by using known Micro-Epsilon Coating Internal Stress Measurements).

Further the amorphous carbon film 100, preferably comprises at least a portion, e.g. a layer, that exhibits a ratio of its average Young's modulus in relation to its average hardness, both properties measured in GPa by using standard nanoindentation techniques, in a range from 7 to 13, preferably in a range from 8 to 12.

The bottom layer 120 has preferably a hardness in a range from 30 GPa to 50 GPa, preferably in a range from 30 GPa to 45 Gpa, and the top layer 150 has preferably a hardness in a range from more than 50 GPa to 80 GPa, more preferably in a range from 55 GPa to 80 GPa, in particular from 55 GPa to 75 GPa.

The bottom layer 120 has preferably a Youngs's modulus in a range from 250 GPa to 350 GPa, and the top layer 150 has preferably a Youngs's modulus in a range from 500 GPa to 800 GPa.

The transition layer 30 has preferably a hardness in a range from more than 50 GPa to 80 GPa, preferably in a range from 55 GPa to 80 GPa or from 55 GPa to 75 GPa, and/or a Youngs modulus in a range from 500 GPa to 800 GPa.

The amorphous carbon film (100), depending on the use can be produced having a particular color or combination of colors.

Therefore, in some cases the amorphous carbon film 100 is produced exhibiting a plurality of color tones instead of a single color, for example having a rainbow color appearance for a human eye in presence of visible light; and in other cases the amorphous carbon film 100 is produced exhibiting a single color, for example having a black color or a gray color appearance for a human eye in presence of visible light.

According to a further preferred embodiment of the present invention the amorphous carbon film 100 comprises at least one layer comprising the highest ratio of the share of the sp³ bond percentages of the C—C bonds in relation to that of the sp² bond percentages along the thickness of the whole amorphous carbon film 100, wherein preferably, for example for obtaining a maximal cutting performance or forming performance, the at least one layer comprising the highest ratio of the share of the sp³ bond percentages of the C—C bonds in relation to that of the sp² bond percentages along the thickness of the whole amorphous carbon film 100 is the top layer 150.

For attaining the desired performance, preferably:
the interface layer 10 is in a range from 3 nm to 200 nm, more preferably in a range from 3 nm to 100 nm, still more preferably in a range between 3 nm and 50 nm, and/or
the thickness of the transition layer 30 is in a range from 10 nm to 200 nm, preferably in a range from 15 nm to 100 nm, still more preferably in a range from nm to 70 nm.

Likewise, also preferably:
the thickness of the bottom layer 120 is in a range from 30 nm to 2000 nm, preferably in a range from 30 nm to 500 nm, still more preferably in a range from 50 nm and 300 nm. and/or
the thickness of the top layer 150 is in a range from 50 nm to 1000 nm, preferably in a range from 50 nm to 500 nm, still more preferably in a range from 70 nm to 350 nm.

For attaining the major wear resistance and toughness, preferably:
the average hardness of the amorphous carbon film 100 is in a range between 50 GPa and 80 GPa, preferably in a range between 50 Gpa and 70 Gpa, and/or
the average Youngs's modulus of the amorphous carbon film 100 is in a range between 500 GPa and 800 GPa, more preferably in a range between 600 GPa and 750 GPa.

The amorphous carbon film according to the present invention preferably exhibits a coefficient of friction measured by ball on disk test in a range between 0.05 and 0.15.

The present invention relates not only to the above described embodiments in separated form but also include all possible combinations thereof.

A preferred method for producing a coated substrate according to any of the precedent embodiments and combinations thereof comprises following process steps:
providing a substrate having a surface made of a first material 1 to be coated,
depositing an amorphous carbon film 100 by using a PVD process, where the PVD process involves cathodic arc evaporation of one or more graphite targets and application of a negative bias voltage to the substrate to be coated, where the absolute value of the bias voltage is varied during deposition of the amorphous carbon film 100 in such a manner that the ratio of the share of the sp3 bond percentages of the C—C bonds in relation to that of the sp2 bond percentages along its thickness vary in such a manner that it is has its lowest value at the beginning of the deposition of the amorphous carbon film 100 and it has its lowest value at the end of the deposition of the amorphous carbon film, wherein at the beginning of the amorphous carbon film 100 deposition process the absolute value of the bias voltage applied is lower than at the end of the amorphous carbon film 100 deposition process.

The absolute bias voltage applied during deposition of the amorphous carbon film 100 is selected preferably varying in a range from 0 V to 200 V, more preferably from 10 V to 180 V, still more preferably from 10 V to 150 V.

For the deposition of different layers within the amorphous carbon film 100, the inventors recommend to maintain as possible a constant bias voltage value for the deposition of each different layer with same defined properties along the same layer.

The absolute arc current applied to the one or more graphite targets during deposition of the amorphous carbon film 100 is selected preferably to be at value in a range from 50 A to 110 A.

During deposition of the amorphous carbon film 100, preferably at least first a bottom layer 120 and afterwards a top layer 150 are deposited, wherein the bias voltage in absolute value used during deposition of the bottom layer 120 is lower than the bias voltage in absolute value used during deposition of the top layer 150,

More preferably:
for the deposition of the bottom layer (120) a negative bias voltage in a range of absolute value from 0 V to 50 V and an arc current in a range from 50 A to 110 A are used, and/or
for the deposition of the top layer (150) a negative bias voltage in a range of absolute value from 50 V to 200 V preferably from 50 V to 180 V, more preferably from 50 V to 150 V, and an arc current in a range from 50 A to 110 A are used.

For the formation of the interface layer 10, the method comprises preferably following process step:
previous to deposition of the amorphous carbon film 100, producing an interface layer 10 by bombarding the first material 1 with carbon ions originated from at least one carbon target, preferably the at least one carbon target being a graphite target, forming in this manner carbon implanted material which constitutes the interface layer 10, wherein preferably the carbon ions are produced by using a PVD process involving arc evaporation techniques, applying preferably an arc current in a range from 30 A to 50 A, and using preferably a bias voltage in a range between 400 V and 1000 V.

For the formation of the transition layer 30, the method comprises preferably following process step:
after deposition of the interface layer (10) and previous to deposition of the amorphous carbon film (100), producing a transition layer (30) by using a PVD process, where the PVD process involves cathodic arc evaporation of one or more graphite targets and application of a negative bias voltage to the substrate to be coated, where the absolute value of the bias voltage is varied during deposition of the transition layer (30), wherein preferably at the beginning of the transition layer (30) deposition process the absolute value of the bias voltage applied is the same as that used for the formation of the interface layer (10) and it is reduced till an absolute value in a range from 150 V to 200 V.

Preferably the amorphous carbon film (100) is deposited by maintaining the process temperature in a range from 70 to 180, preferably in a range from 80° C. to 170° C., still more preferably in a range from 100° C. and 140° C.

The amorphous carbon film is deposited on said substrate surface in such a manner that an interface layer is formed between the first material of said substrate surface and the amorphous carbon film, wherein the interface layer consists of carbon implanted first material, wherein the thickness of the interface layer is at least 3 nm.

Thus, according to the present invention:
It is conceivable that the amorphous carbon film is designed comprising a variable ratio of the share of the sp3 bond percentages of the C—C bonds in relation to that of the sp2 bond percentages along its thickness, preferably said ratio increasing from the bottom to the top of the amorphous carbon film.
It is thinkable that the amorphous carbon film comprises at least one layer comprising the highest ratio of the share of the sp3 bond percentages of the C—C bonds in relation to that of the sp2 bond percentages along the thickness of the amorphous carbon film.
It is conceivable that the at least one layer comprising the highest ratio of the share of the sp3 bond percentages of the C—C bonds in relation to that of the sp2 bond percentages along the thickness of the amorphous carbon film is preferably deposited as outermost layer 150 (also referred to as top layer 150) of the amorphous carbon film 100.
It is conceivable that the amorphous carbon film 100 can preferably be deposited as multilayer (i.e. comprising at least two layers), wherein these at least two layers are designed in such a manner that they allow attaining outstanding combination of toughness and low residual compressive stress. For having this technical effect, these at least two layers being a bottom layer 120 and a top layer 150, wherein the ratio of the share of the sp3 bond percentages of the C—C bonds in relation to that of the sp2 bond percentages along the thickness of the top layer 150 is higher than that along the thickness of the bottom layer 120. It is conceivable that the amorphous carbon film 100 can comprise at least a portion, e.g. a layer, that is transparent in the visible region, and exhibits interference color, where the color of the amorphous carbon film may be the rainbow color corresponding to a plurality of color tones instead of a single color, or the amorphous carbon film 100 can comprise at least a portion, e.g. a layer, that exhibits a defined color, e.g. a black color appearance.
It is conceivable that the amorphous carbon film preferably comprises at least a portion, e.g. a layer, that exhibits a ratio of its average Young's modulus in relation to its average hardness, both properties measured in GPa by using standard nanoindentation techniques, in a range from 7 to 13, preferably in a range from 8 to 12.
It is conceivable that the thickness of the interface layer is in a range from 3 nm to 200 nm, preferably in a range from 3 nm to 100 nm.
It is conceivable that the thickness of the interface layer can still more preferably be in a range from 3 nm to 50 nm.
It is also thinkable that the interface layer does not comprise any droplets.
It is conceivable that the average hardness of the amorphous carbon film is in a range between 50 GPa and 80 GPa, preferably in a range between 50 GPa and 70 GPa.
The average Youngs's modulus of the amorphous carbon film may be in a range between 500 GPa and 800 GPa, preferably in a range between 600 GPa and 750 GPa.
It is also thinkable that the amorphous carbon film is formed as multilayered film, comprising at least two tetrahedral hydrogen-free amorphous carbon layers, preferably more than two tetrahedral hydrogen-free amorphous carbon layers.
The amorphous carbon film may exhibit a coefficient of friction measured by ball on disk test in a range between 0.05 and 0.15.
In another aspect of the invention it is conceivable, a method for producing a coated substrate according to the invention is provided. The material forming the interface layer is produced by carbon ions bombardment of the first material forming the substrate surface of the tool to be coated without any metallic layer, and the amorphous carbon film is deposited directly on the second material by using a PVD process, where the PVD process involves cathodic arc evaporation of graphite targets and application of a negative bias voltage to the substrate to be coated, where the absolute value of the bias voltage is varied during deposition of the amorphous carbon film in such a manner that the bias voltage at the beginning of the amorphous carbon film 100 deposition process is higher in absolute value than the bias voltage at the end of the amorphous carbon film deposition process.
It is thinkable that the bias voltage in absolute value varies stepwise.
It is also conceivable that the variation of the bias voltage in absolute value is in a range from 0 V to 600 V, preferably in a range from 10 V to 500 V.
It is further thinkable that the variation of the arc current in absolute value is in a range from 35 A to 80 A, preferably in a range from 40 A to 70 A.
The amorphous carbon film may be deposited by maintaining the process temperature in a range from 80° C. and 170° C., preferably in a range from 100° C. and 140° C.
It is conceivable that during the amorphous carbon film deposition process the coating parameters are adjusted for reducing droplets in the amorphous carbon film.

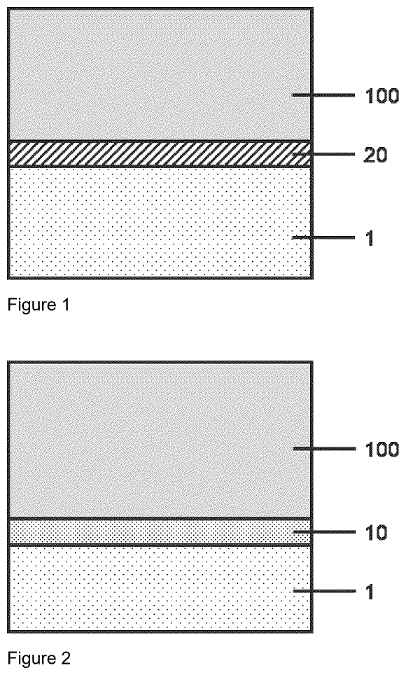

In order to explain the invention in more detail some examples will be explained below and details will be illustrated in the FIGS. 1 to 10. The examples and illustrations should not be understood as a limitation of the present invention.

Example of deposition of a coating according to the present invention:

Substrates were coated with a coating consisting.of hydrogen-free tetrahedral amorphous carbon.

Substrates of different types and materials were cleaned and introduced in a vacuum coating chamber of a coating plant of the type DOMINO SC and DOMINO L of the company Oerlikon.

In particular following substrates were coated and investigated and/or tested:
1) quality reference samples made of:
   a. steel type: 90MnCrV8 and 1.2842 having hardness higher than 62 HRC, arithmetic average roughness Ra≤0.05 μm, dimensions Ø22 mm×5.6 mm,
   b. cemented carbide SPGN 120308 6 wt % Co, dimensions 12×12 mm, thickness: 3.18 mm), and
2) cutting tools and forming tools of the type:
   a. drills, mills, reamers, taps, punches, cutters, molds, dies, trimming,
   b. flanging tools made up of carbide, high speed steel, D2 steel, H13 steel and CuBe tools, respectively.

Vacuum was produced within the vacuum coating chamber till attaining vacuum conditions corresponding to a pressure of 0.08 Pa.

Subsequently an argon gas flow in a range from 50 sccm up to 300 sccm was used as process gas, preferably the argon flow was maintained at values in a range from 150 sccm up to 250 sccm. The argon gas flow was introduced in the vacuum coating chamber and the flow varied during the process depending on the process pressure adjusted, i.e. the process was conducted pressure controlled.

The total process pressure during deposition of the amorphous carbon coating was maintained at a pressure value in a range from 0.05 Pa up to 1.5 Pa.

### Formation of Carbon-Enriched Interface (Interface Layer 10)

Before deposition of the coating, the substrate surfaces to be coated were bombarded with carbon ions for producing carbon implantation at the interface between the substrate surface to be coated and the coating being deposited on the substrate, in order to increase adhesion of the coating to the substrate surface without deteriorating tool performance by including an adhesion layer between the substrate surface and the coating.

During bombarded with carbon ions, it was attained that the carbon ions penetrate the substrate surface to be coated till a deepness in a range from 3 nm up to 30 nm, in this manner an carbon enriched interface layer was produced and observed SEM pictures below, which clearly displays carbon imbedded in the substrate material, for example carbon imbedded in a steel matrix.

After forming the interface layer, the process parameters were adjusted for initiating the formation of the amorphous carbon film. For the formation of the amorphous carbon film, graphite targets were used as coating source material, wherein carbon from the graphite targets was vaporized by using a cathode arc ion plating method in an atmosphere containing argon gas as the only one process gas entering into the vacuum coating chamber.

The inventors observed that impressively the absence of a metal interlayer (e.g. the absence of a Cr interlayer that is usually deposited for increasing adhesion between substrate and coating) resulted in a considerable further enhancement of the adhesion of the coating to the substrates. The inventors suppose that this additional considerable improvement can be caused by the fact that no droplets are formed at the interface between the substrate surface to be coated and the coating, because no metal layer is deposited in between and normally during deposition of a metal interlayer also droplets are generated and deposited together with the metal interlayer, hence the absence of droplets results in an increased adhesion.

The coating consisting of hydrogen-free tetrahedral amorphous carbon was deposited afterwards by using cathodic arc evaporation techniques.

More detailed description of the method used for coating the substrates in the above mentioned inventive Example:

The substrates mentioned above, after being cleaned, introduced in the interior of the vacuum coating chamber, and drawing vacuum, were subjected to following further process steps:

### Pre-Heating

The substrate were heated up to about 100° C. in the same vacuum coating chamber used for carbon implantation. For the pre-heating step radiation heaters present in the vacuum coating chamber were used.

### Etching

The substrate surfaces to be coated were etched with argon ions. The etching was carried out by a so-called “advanced energy glow discharge” (AEGD) technology. In the vacuum coating chamber, titanium targets were activated behind a shutter by means of an arc with target current of 80 A. The titanium ions produced were captured by the shutter. With a positive potential applied on a rod within the chamber, the electrons produced by this process were conducted to etch the substrate surfaces to be coated. During this phase, the argon flow was fed into the vacuum coating chamber and was pressure-controlled at pressure value of about 1 Pa. The ionized argon (Ar+) produced in this manner was directed towards the substrate surfaces to be coated by applying a negative bias voltage to the substrates having absolute value in a range from 50 V up to 200 V. The etching of the substrate surfaces to be coated was then done in this manner by ion bombardment.

Carbon ion bombardment step for forming the inventive carbon enriched interface (interface layer 10) as already mentioned above—More detailed concrete example

At a process pressure in a range from 0.01 Pa and 0.02 Pa, for example about 0.015 Pa and by using an argon flow in a range from 50 sccm and 300 sccm, for example about 250 sccm carbon doping into the steel or cemented carbide substrate is carried out. The argon was introduced by means of gas showers directly in front of the carbon-containing targets (e.g. graphite-targets). The carbon-containing targets were ignited by trigger wire and operated at a target current in a range from 40 A up to 55 A, for example of about 45 A. The resulting carbon ions (C+) were then accelerated onto the substrate surface to be coated by applying a negative bias voltage in a range in absolute value in a range from 500 up to 700 V, for example about 500 V. This has led to a minor implantation of carbon ions into the substrate below the substrate surface to be coated.

### Deposition of the Carbon Transition Layer (Transition Layer 30)

The value of the negative bias voltage in absolute value was reduced, for example from 500 V to 250 V or to a lower value.

Deposition of the hydrogen-free tetrahedral amorphous carbon film (also called ta-C film or amorphous carbon film 100) The hydrogen-free tetrahedral amorphous carbon film (ta-C film) was produced at the same process pressure used in the previous process step but by using an argon flow in a range from 50 sccm up to 80 sccm, for example between 60 sccm and 70 sccm. In this case, the carbon-containing targets (e.g. graphite targets) were operated at a higher target current, e.g. in a range from 60 A up to 90 A. The absolute value of the negative bias voltage is increased at a given rate (e.g. the increment conducted describing a ramp or stepwise, e.g. in two steps for forming two different layers, e.g. a bottom layer 120 and a top layer 150) over the entire coating process (here it is meaning entire deposition process but of the amorphous carbon film 100) time from 10 V up to 250 V or from 10 V up to 100 V or less.

The target current of the carbon-containing targets was kept constant.

Applying a lower bias voltage at the beginning of the coating process had the advantage that a ta-C layer (e.g. a bottom layer 120) with lower hardness was produced.

Afterwards, further increasing the bias voltage in absolute value allowed depositing a ta-C layer having a higher hardness (i.e. a harder ta-C layer, e.g. a top layer 150), with hardness for example in a range from 50 GPa up to 80 GPa measured by using known nanoindentation methods (e.g. by using a Fisherscope Nanoindentation Device).

By using a negative bias voltage of about −80 V and a substrate temperature close to 120° C., it was possible to attain a considerable increment in the proportion of sp3 bonds and at the same time a reduction of the proportion of sp2 bonds. This has resulted in a very hard diamond-like top layer having a significantly higher hardness than the rest of the coating of about 60-80 GPa, i.e. in a range from 60 GPa to 80 GPa. This top layer with considerably higher hardness was found to provide a significant advantage for cutting applications as we as for forming applications.

For the analysis of the properties of the inventive coatings various standard characterization tests or technologies for characterization were used, such as:
Scanning electron microscopy (SEM),
Nano scratch test for comparison of coating adhesion properties,
Secondary ion mass spectrometry,
Transmission Emission Microscopy (TEM)
Micro-Epsilon Coating Internal Stress Measurements (by using the known calculation of residual stress—also called internal stress—of thin strips by using DIN technical report 30 {in German: DIN-Fachbericht 39}, see in particular page 163).

Figure captions:

FIG. 1: shows schematically the design of a coated substrate according to the prior art comprising a substrate 1, a metallic adhesion layer 20 and an amorphous carbon film 100.

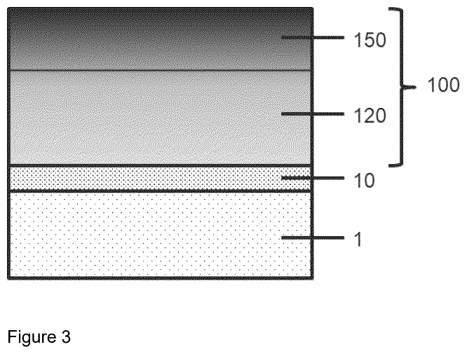

FIG. 2: shows schematically the design of a coated substrate according to the present invention comprising a substrate 1, an interface layer 10 and an amorphous carbon film 100.

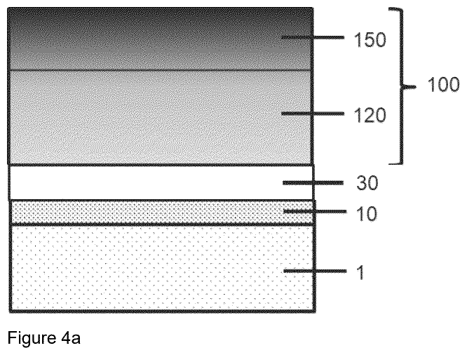

FIG. 3: shows schematically the design of a preferred embodiment of a coated substrate according to the present invention, in which the amorphous carbon film 100 comprises a top layer 150 comprising a higher amount of sp3 bonds than the lower layer 120.

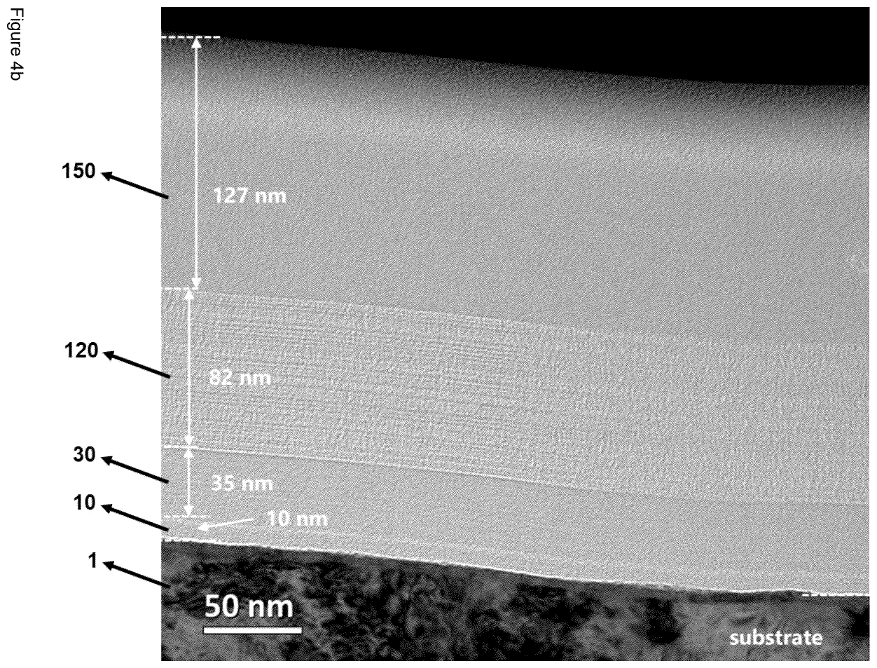

FIG. 4: FIG. 4a shows schematically the design of a further preferred embodiment of a coated substrate in which the coating have a multilayered structure according to the present invention, in which an interface layer 10 and a transition layer 30 are deposited between the substrate surface 1 and the amorphous carbon film 100, and the amorphous carbon film 100 comprises a bottom layer 120 and a top layer 150; FIG. 4b displays SEM images showing the cross-section of a coated substrate according to the present invention having a multilayered structure as shown schematically in FIG. 4a.

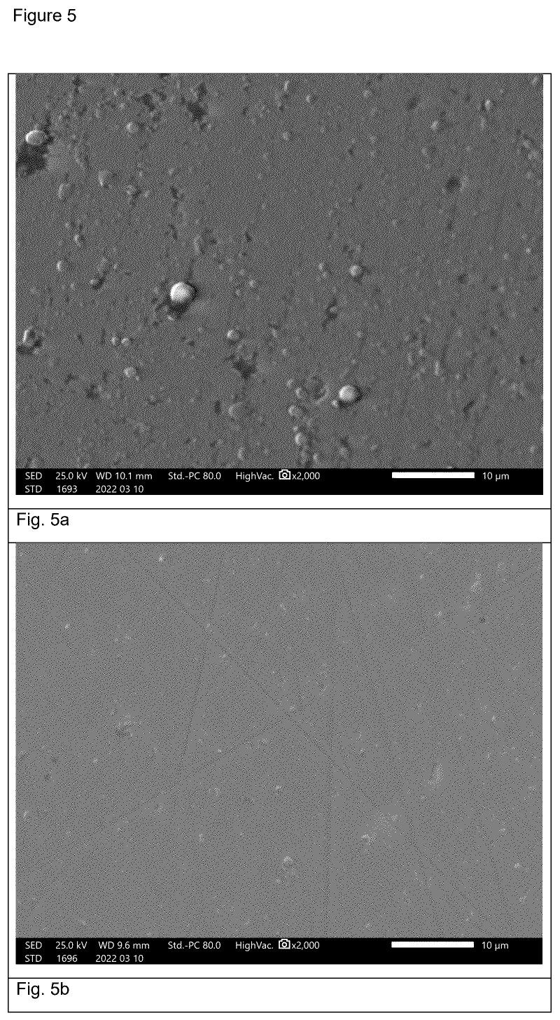

FIG. 5: displays two SEM surface images showing the differences between the surface quality of a surface of a coated substrate according to the prior art (FIG. 5a) and a coated surface of a coated substrate according to the present invention (FIG. 5b).

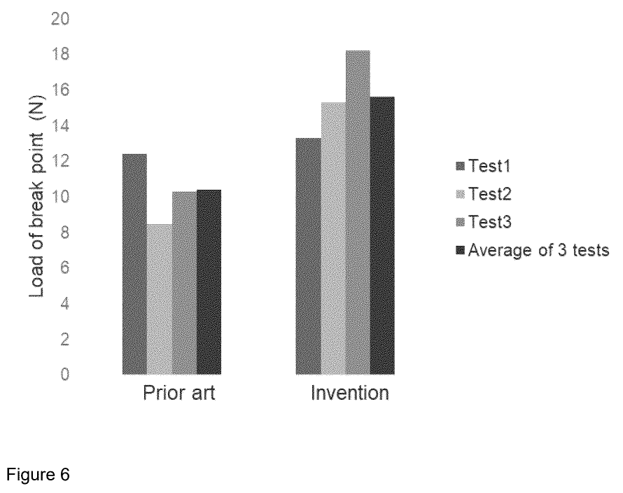

FIG. 6: shows a comparison between the coating adhesion tests results of a coated substrate according to the prior art and a coated substrate according to the present invention. The coating adhesion was tested under same conditions with a Nano Scratch Test. The tests were conducted with a starting load of 0.3 N and speed of scratch was 5 mm/s.

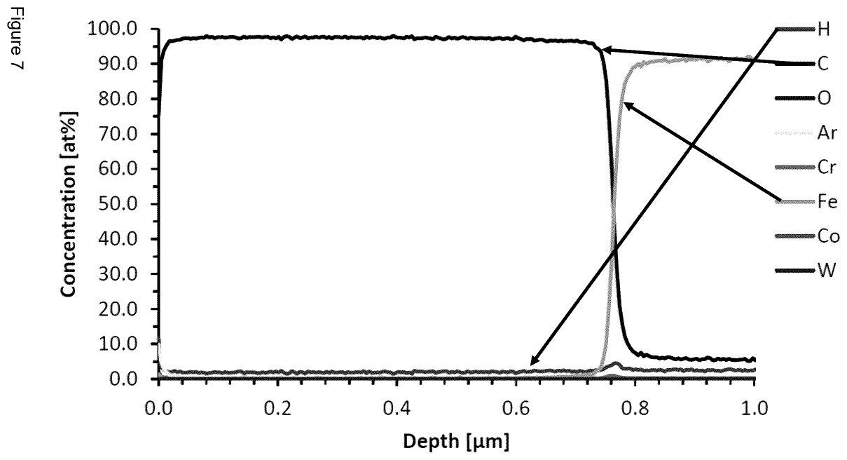

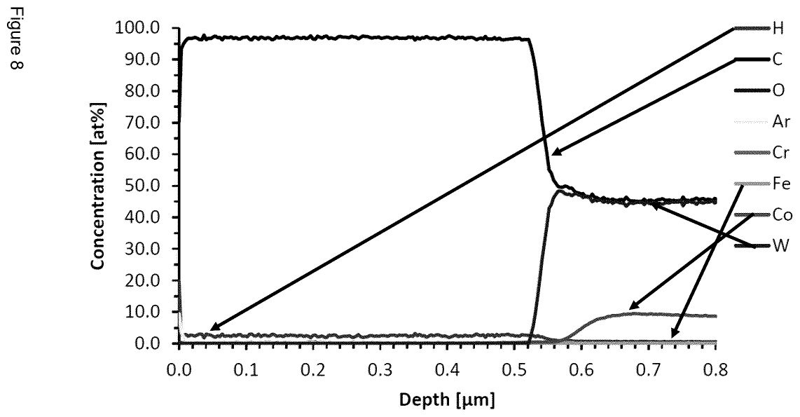

FIGS. 7 and 8 show SIMS of the coating claimed in this patent on 100Cr6 Steel and WC:Co substrates. Minor Cr (less than 1 at. %) impurity was detected due to conditioning of the coating chamber using metallic chromium. FIG. 7 shows specifically a SIMS depth profile of the inventive metal free ta-C coating film on 100Cr6 steel substrate and FIG. 8 shows specifically a SIMS depth profile of the same inventive metal free coating with a ta-C coating film deposited on a substrate of WC:Co (cemented carbide).

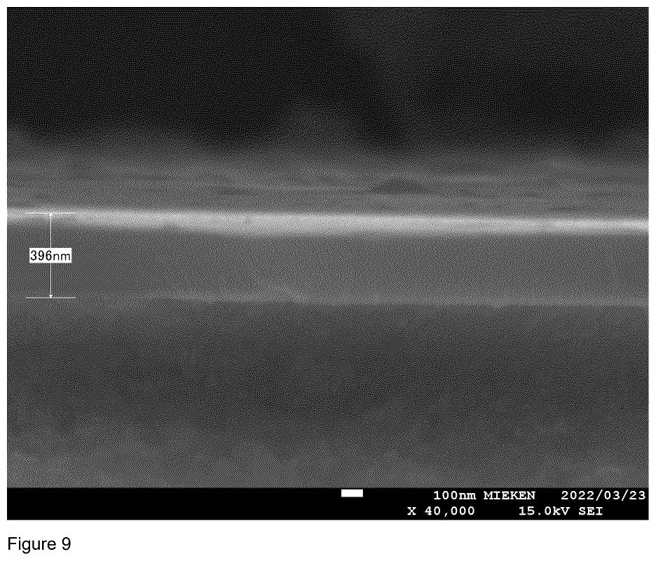

FIG. 9 SEM cross section of as deposited metal free coating with a taC coating according to the present invention.

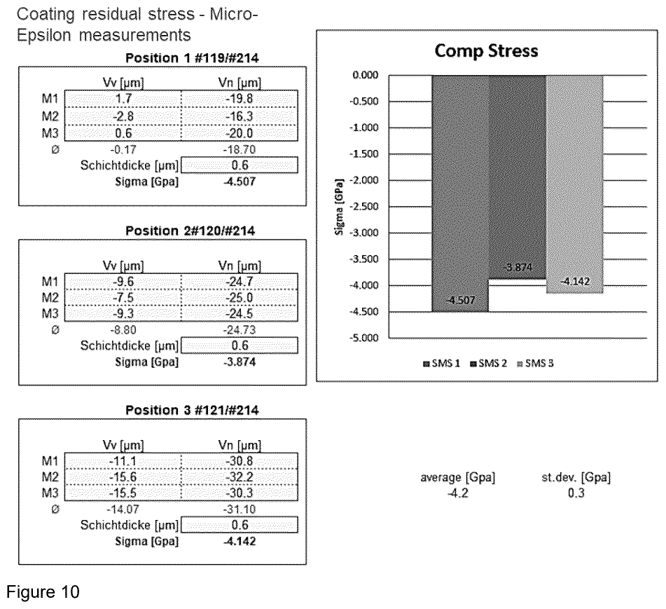

FIG. 10 Coating residual stress of three different inventive coatings comprising an interface layer 10, a transition layer 30, and an amorphous carbon film 100 comprising a bottom layer 120 and a top layer 150—measured by using Micro-Epsilon Coating Internal Stress Measurements.

The residual stress values (residual compressive stress values in all these cases) shown in FIG. 10 are from three different inventive coatings but all three having multi-layered structure as shown in FIG. 4a and whole coating thickness of 600 nm. The residual compressive stress of the three inventive coating variants was respectively was of −4.2 GPa, which is considerable low in comparison with that of comparative coatings from the state of the art that not have the inventive structure. For example, the residual compressive a coating of a state of the art having structure as shown in FIG. 1 and whole coating thickness of 400 nm had a residual compressive stress of −6.128 GPa, which is very high in comparison with the inventive variants whose stress measurements are shown in FIG. 10.

The present invention is suitable for depositing very thin films allowing coating of precision tools and also components for different applications, e.g.:
cutting tools having sharp edges and/or complexes geometries as well as forming tools, e.g. molds requiring a very high precision (e.g. no modification of the geometry),
components or surfaces used for semiconductor applications.

Further the present invention allows coating of a very broad range of possible substrate materials, e.g. aluminum Al and Al alloys), copper-beryllium (Cu—Be and Cu—Be alloys), all steels types, all cemented carbide types as well cermet, etc.

1. A coated substrate, comprising a coated surface, said coated surface formed by a substrate surface made of a first material (1) and a coating system, applied on said substrate surface, said coating system comprising an amorphous carbon film (100), wherein the amorphous carbon film (100) is a tetrahedral hydrogen-free amorphous carbon film in which a share of sp³ bond percentages of the C—C bonds exceeds that of sp² bond percentages, wherein:
the amorphous carbon film (100) is designed comprising a variable ratio of the share of the sp³ bond percentages of the C—C bonds in relation to that of the sp² bond percentages along its thickness, wherein said ratio increasing.

2. The coated substrate according to claim 1, wherein:
the amorphous carbon film (100) is formed as multilayered film comprising at least two tetrahedral hydrogen-free amorphous carbon layers, wherein the at least two layers are:
a bottom layer (120) comprising a region of the amorphous carbon film (100) nearest to the substrate, and
a top layer (150) comprising the region of the amorphous carbon film (100) most distant from the substrate, wherein said ratio of the share of the sp³ bond percentages of the C—C bonds in relation to that of the sp² bond percentages is higher along the thickness of the top layer (150) than that along the thickness of the bottom layer (120).

3. The coated substrate according to claim 2, wherein:
the top layer (150) is an outermost layer of the amorphous carbon film (100).

4. The coated substrate according to claim 1, wherein:
the amorphous carbon film (100) is deposited on said substrate surface in such a manner that an interface layer (10) is formed between the first material (1) of said substrate surface and the amorphous carbon film (100), wherein the interface layer (10) consists of carbon implanted material, the carbon implanted material being formed of first material plus carbon implanted into it, wherein the thickness of the interface layer (10) is at least 3 nm.

5. The coated substrate according to claim 4, wherein:
a transition layer (30) is deposited between the interface layer (10) and the amorphous carbon film (100), wherein the transition layer (30) is a carbon layer improving interfacial transition between the interface layer (10) and the amorphous carbon film (100).

6. The coated substrate according to claim 5, wherein:
the transition layer (30) is a tetrahedral hydrogen-free amorphous carbon layer.

7. The coated substrate according to claim 1, wherein:
the amorphous carbon film (100) has a low residual compressive stress, corresponding to a value in absolute value not higher than 5.5 GPa.

8. The coated substrate according to claim 1, wherein:
the amorphous carbon film (100) comprises at least a portion, e.g. a layer, that exhibits a ratio of its average Young's modulus in relation to its average hardness, both properties measured in GPa by using standard nanoindentation techniques, in a range from 7 to 13.

9. The coated substrate according to claim 2, wherein:
the bottom layer (120) has hardness in a range from 30 GPa to 50 GPa, and
the top layer (150) has hardness in a range from more than 50 GPa to 80 GPa.

10. The coated substrate according to claim 2, wherein:
the bottom layer (120) has Youngs modulus in a range from 250 GPa to 350 GPa, and
the top layer (150) has Youngs modulus in a range from 500 GPa to 800 GPa.

11. The coated substrate according to claim 5, wherein:
the transition layer (30) has:
at least hardness in a range from more than 50 GPa to 80 GPa,
Youngs modulus in a range from 500 GPa to 800 GPa.

12. The coated substrate according to claim 1, wherein:
the amorphous carbon film (100) exhibits a plurality of color tones instead of a single color, for example having a rainbow color appearance for a human eye in presence of visible light.

13. The coated substrate according to claim 1, wherein:
the amorphous carbon film (100) exhibits a single color, for example having a black color or a gray color appearance for a human eye in presence of visible light.

14. The coated substrate according to claim 1, wherein:
the amorphous carbon film (100) comprises at least one layer comprising a highest ratio of the share of the sp³ bond percentages of the C—C bonds in relation to that of the sp² bond percentages along the thickness of a whole amorphous carbon film (100).

15. The coated substrate according to claim 14, wherein:
the at least one layer comprising the highest ratio of the share of the sp³ bond percentages of the C—C bonds in relation to that of the sp² bond percentages along the thickness of the whole amorphous carbon film (100) is a top layer (150).

16. The coated substrate according to claim 4, wherein the thickness of:
at least the interface layer (10) is in a range from 3 nm to 200 nm, or
the thickness of a transition layer (30) is in a range from 10 nm to 200 nm.

17. The coated substrate according to claim 4, wherein:
at least the thickness of a bottom layer (120) is in a range from 30 nm to 2000 nm or
the thickness of a top layer (150) is in a range from 50 nm to 1000 nm

18. The coated substrate according to claim 1, wherein:
an average hardness of the amorphous carbon film (100) is in a range between 50 GPa and 80 GPa.

19. The coated substrate according to claim 1, wherein
an average Youngs's modulus of the amorphous carbon film (100) is in a range between 500 Gpa and 800 Gpa.

20. Coated substrate according to claim 1, wherein the amorphous carbon film exhibits a coefficient of friction measured by ball on disk test in a range between 0.05 and 0.15.

21. A method for producing a coated substrate according to claim 1, wherein comprising following process steps:
providing a substrate having a surface made of a first material (1) to be coated,
depositing an amorphous carbon film (100) by using a PVD process, where the PVD process involves cathodic arc evaporation of one or more graphite targets and application of a negative bias voltage to the substrate to be coated, where an absolute value of the bias voltage is varied during deposition of the amorphous carbon film (100) in such a manner that the ratio of the share of the sp³ bond percentages of the C—C bonds in relation to that of the sp² bond percentages along its thickness vary in such a manner that it is has its lowest value at a beginning of the deposition of the amorphous carbon film (100) and it has its lowest value at an end of the deposition of the amorphous carbon film, wherein at the beginning of the amorphous carbon film (100) deposition process the absolute value of the bias voltage applied is lower than at the end of the amorphous carbon film (100) deposition process.

22. The method according to claim 21, wherein:
the absolute bias voltage applied during deposition of the amorphous carbon film (100) varied in a range from 0 V to 200 V.

23. The method according to claim 21, wherein:
during deposition of the amorphous carbon film (100) an arc current in a range from 50 A to 110 A, is applied to the one or more graphite targets.

24. The method according to claim 21, wherein during deposition of the amorphous carbon film (100) at least first a bottom layer (120) and afterwards a top layer (150) are deposited, wherein the bias voltage in absolute value used during deposition of the bottom layer (120) is lower than the bias voltage in absolute value used during deposition of the top layer (150).

25. The method according to claim 21, wherein comprising following process step:
previous to deposition of the amorphous carbon film (100), producing an interface layer (10) by bombarding the first material (1) with carbon ions originated from at least one carbon target, forming in this manner carbon implanted material which constitutes the interface layer (10).

26. The method according to claim 25, wherein comprising following process step:
after deposition of the interface layer (10) and previous to deposition of the amorphous carbon film (100), producing a transition layer (30) by using a PVD process, where the PVD process involves cathodic arc evaporation of one or more graphite targets and application of a negative bias voltage to the substrate to be coated, where the absolute value of the bias voltage is varied during deposition of the transition layer (30).

27. The method according to claim 21, wherein:
the amorphous carbon film (100) is deposited by maintaining a process temperature in a range from 70 to 180.
